(19) United States
(12) Patent Application Publication
(10) Pub. No.: US 2025/0324612 A1
(43) Pub. Date: Oct. 16, 2025

(54) CONFIGURABLE-PERFORMANCE RESISTIVE MEMORY AND ASSOCIATED METHODS

(71) Applicant: COMMISSARIAT À L'ÉNERGIE ATOMIQUE ET AUX ÉNERGIES ALTERNATIVES, PARIS (FR)

(72) Inventors: Gabriele NAVARRO, GRENOBLE CEDEX 09 (FR); Giusy LAMA, GRENOBLE CEDEX 09 (FR)

(21) Appl. No.: 18/866,738

(22) PCT Filed: May 12, 2023
(86) PCT No.: PCT/EP2023/062730

§ 371 Date: Nov. 18, 2024

(30) Foreign Application Priority Data
May 16, 2022 (FR) 2204617

(51) Int. Cl. H10B 63/10; G11C 13/00; H10N 70/00; H10N 70/20

(52) U.S. Cl. CPC H10B 63/10; G11C 13/0004; G11C 13/0069; H10N 70/231; H10N 70/882; G11C 2013/0083

(57) ABSTRACT

A resistive memory includes at least one first layer, including a titanium-based material, the titanium-based material being conductive; at least one second layer, extending over the at least one first layer, including a first phase change material, the first phase change material being able to be doped with titanium; a first electrode and a second electrode, the first and second layers separating the first electrode from the second electrode by electrically connecting in series the first electrode to the second electrode, the first electrode being in contact with the at least one first layer or, when there are several first layers, in contact with one of the first layers.

### TECHNICAL FIELD OF THE INVENTION

The technical field of the invention is that of resistive memories and more particularly Phase Change Random Access Memories (PCRAMs).

### TECHNOLOGICAL BACKGROUND OF THE INVENTION

Resistive memories can offer long-lasting storage while minimising energy consumption. Indeed, these memories are non-volatile, so the information is encoded in a resistance value in the memory and electrical energy is only required when reading the information (i.e. measuring the resistance value) or writing the information to the resistive memory (also referred to as switching). Resistive memories are therefore good candidates for storing permanent information in a device or integrated circuit. For example, they are implemented in a back end of line of a device or integrated circuit, to store information over a long period (such as calculation instructions or calculation results).

Recent developments in resistive memories relate to, among other things, the reduction in the amplitude of the switching current, for improving the switching rate of resistive memories. The paper [“Thermal Barrier Phase Change Memory” J. Shen & al, ACS Appl. Mater. Interfaces, January 2019, 11, 5, 5336-5343] discloses, for example, a resistive memory with reduced switching time. The resistive memory disclosed comprises a plurality of layers of phase change material, herein Sb₂Te₃, separated by semi-metallic layers, herein TiTe₂. This arrangement of Sb₂Te₃/TiTe₂ bilayers makes it possible to obtain a switching current reduced by about 85% and thus offers a switching time reduced to about 10 ns.

This type of memory can therefore be contemplated as random access memory and can be implemented in a logic functional block of a device or integrated circuit, also referred to as the “front end of line”.

While a resistive memory Sb₂Te₃/TiTe₂ may have a reduced switching time, by virtue of the reduced switching current, it degrades information storage durability (also referred to as retention durability), which means that it can no longer be considered for long-term storage at the back end of line.

It is therefore necessary, upon manufacturing a device or integrated circuit, to make different types of resistive memory in order to obtain either long-term storage or high switching rate. The manufacture of the device or integrated circuit is therefore more complex because it requires depositing different materials and therefore additional masking and unmasking steps according to the materials deposited and targeted.

There is therefore a need to provide a resistive memory whose performance can be adjusted.

### SUMMARY OF THE INVENTION

The invention at least partially solves the problems discussed previously, by providing a method for initialising a resistive memory in order to modify its performance and more particularly its switching rate or its retention level.

For this, the invention relates to a method for initialising a non-initialised resistive memory, said non-initialised resistive memory comprising:
at least one first layer, comprising a titanium-based material, said titanium-based material being conductive;
at least one second layer, extending over said at least one first layer, comprising a first phase change material, said first phase change material being able to be doped with titanium;
   the method comprising a step of circulating an electric current, referred to as an initialisation current, in each of the first and second layers, the initialisation current being dimensioned to generate a temperature gradient within each of the first and second layers involving melting of at least one part of the titanium-based material of each first layer over its entire thickness and of at least one part of the first phase change material of each second layer, said melting resulting in forming, from the first phase change material and the titanium-based material, of a second phase change material comprising titanium.

By initialisation current dimensioned to perform some function (in particular the generation of the thermal gradient), it is meant that the initialisation current is adapted to perform this function.

By resistive memory, it is meant a memory which can have at least two states, wherein reading the current state of the memory can be performed by measuring its resistance.

By titanium-based material, it is meant a material in which one of the constituents is titanium. For example, it is a titanium alloy such as TiTe.

By conductive material, it is meant an electrical conductor and advantageously a thermal conductor. The electrical resistivity of the titanium-based material is, for example, less than 1000 μΩ·cm, or even less than or equal to 700 μΩ·cm. The resistivity is preferably measured at a temperature of less than 700° C., or even less than or equal to 400° C.

By phase change material, it is meant a material able to switch, under the action of a parameter such as an electric current, from a first state to a second state or from the second state to the first state, the first state having a first resistivity and the second state having a second resistivity, different from the first resistivity. The first state corresponds, for example, to a first phase of said material and the second state corresponds, for example, to a second phase of said material. The first phase may be a crystalline phase and the second phase may be an amorphous phase.

By able to be doped with titanium, it is meant that titanium can electronically interact with the first phase change material and modify at least one switching property of said first phase change material. A phase change material doped by means of titanium, for example, has its phase change temperature lowered.

By electric current circulation, it is meant the flow of an electric current through each of the first and second layers.

By generating a temperature gradient, it is meant locally modifying the temperature of said layers by supplying an amount of heat dissipated by Joule effect.

By melting at least one part of a titanium-based material of a first layer over its entire thickness, it is meant that at least one portion of said titanium-based material shifts to the molten state, said portion reaching two faces of said first layer, said two faces being opposite to each other.

By forming a second phase change material, it is meant mixing the molten materials, herein the titanium base material and the first phase change material, and combining the molten first phase change material with titanium from said molten titanium base material.

The non-initialised resistive memory makes it possible to store information in the first phase change material of each second layer. Circulation of the initialisation current in the resistive memory enables a so-called “active” region to be formed in the memory, comprising the second phase change material. The second phase change material comprises the first phase change material doped with titanium from the titanium-based material. The active region can store information, but has a higher switching rate than the switching rate of the first phase change material. The switching rate depends on the concentration of titanium doping the first phase change material, which in turn depends on the volume of the active region, which in turn depends on the current that has flowed through both layers. Thus circulation of a predetermined electrical current in the resistive memory enables performance of said memory to be configured.

Further to the characteristics just discussed in the preceding paragraph, the initialisation method according to the invention may have one or more additional characteristics from among the following, considered individually or according to any technically possible combinations:
the second phase change material has a concentration of titanium, derived from the titanium-based material, the initialisation current being selected to control said concentration;
said method comprises a step of determining a minimum initialisation current associated with a maximum concentration of titanium in the second phase change material, said maximum concentration of titanium in the second phase change material being strictly lower than the concentration of titanium in the pure titanium-based material, the initialisation current used during the circulation step being greater than or equal to the minimum initialisation current;
the minimum initialisation current is greater than or equal to a read current and a switching current of the initialised resistive memory;
said method comprises a step of determining a maximum initialisation current, the maximum initialisation current being associated with a minimum concentration of titanium in the second phase change material, said minimum concentration of titanium in the second phase change material being less than or equal to 1/100, the initialisation current used in the circulation step being less than or equal to the maximum initialisation current;
the non-initialised resistive memory has at least one intermediate active region, each intermediate active region being disposed between a first layer and a second layer, each intermediate active region comprising at least one third phase change material comprising titanium, the initialisation current also circulating within each intermediate active region, the initialisation current also being dimensioned to generate a temperature gradient within each intermediate active region also involving melting of at least one part of the third phase change material of each intermediate active region, said melting resulting in forming, from the first phase change material and the titanium-based material and the third phase change material, a second phase change material comprising titanium;
said method comprises a step of solidifying the second phase change material so as to form of at least one solid region, referred to as an “active region”, comprising at least one part of the second phase change material;
the titanium-based material comprises a first element, referred to as the “carrier element”, which is neutral with respect to switching properties of the first phase change material, the carrier element preferably being germanium, antimony or tellurium;
the titanium-based material comprises impurities, introduced intentionally or unintentionally, which can exert influence on electronic properties of the first phase change material, said impurities advantageously being carbon or nitrogen;
the titanium-based material is selected so that melting of at least one part of each first layer also dissociates at least one part of the constituents of said titanium-based material; by dissociate, it is meant that the chemical bond of part of the constituents of said material can be broken;
dissociation of the constituents of said titanium-based material can also be achieved by heating said material by means of an electrical pulse preferably having an intensity of less than 100 mA, or even less than 10 mA, and even more preferably less than or equal to 5 mA; the electrical pulse preferably having a duration of less than 10 μs, or even less than 1 μs, and even more preferably less than 500 ns;
the titanium-based material has a resistivity of less than 1000 μΩ·cm and preferably less than or equal to 700 μΩ·cm;
the first phase change material comprises a titanium concentration lower than the titanium concentration of the pure titanium material, the first phase change material comprising a titanium concentration of preferably zero;
the titanium-based material comprises a titanium concentration such that heat treatment of said material at a temperature of 400° C. or less modifies its resistivity by less than 70%, or even less than 40%, the titanium concentration preferably being between 25% and 65%, or even between 40% and 50%, for example equal to 45%;
the first phase change material is an alloy, preferably stoichiometric; by stoichiometric alloy, it is meant that the stoichiometric coefficients of each constituent of said alloy are natural integers; a stoichiometric alloy is also thermodynamically stable and does not give rise to phase separation, for example during a manufacturing step or a programming step;
the first phase change material is a binary alloy or a ternary alloy comprising germanium, antimony, tellurium, gallium or selenium; said first phase change material may also comprise traces, intentionally or unintentionally introduced, of nitrogen, carbon, boron, oxygen or silicon;
the first and second layers each have a melting temperature in the range ]400° C.; 1000° C.] and preferably in the range [450° C.; 700° C.]; in other words, the titanium-based material and the first phase change material each have a melting temperature in the range ]400° C.; 1000° C.[ and preferably in the range [450° C.; 700° C.];
the thickness of each second layer is greater than the thickness of each first layer and preferably greater than four times, or even twenty times, the thickness of each first layer, the thickness of each first layer preferably being between 0.5 nm and 20 nm and the thickness of each second layer preferably being between 10 nm and 200 nm;
the non-initialised resistive memory comprises a first electrode and a second electrode, the first electrode being in contact with a first layer, the second electrode extending over a second layer, the first electrode having a width less than a width of each first layer, the second electrode having a width greater than the width of the first electrode; by in contact, it is meant that there is no intermediate element between the first electrode and the first layer in contact;
the non-initialised resistive memory comprises a first electrode, a second electrode, two second layers and a first layer, each of the second layers extending over one of the faces of the first layer, the first electrode being in contact with one of both second layers, the second electrode being in contact with another of both second layers, the first and second electrodes each having a width greater than or equal to the width of the first layer;
the resistive memory comprises alternating first and second layers.

The invention also relates to an initialised memory obtained after implementation of the initialisation method according to the invention, said initialised resistive memory comprising:
at least one first layer, comprising a titanium-based material;
at least one second layer, extending over said at least one first layer, comprising a first phase change material; and
at least one active region, each active region being disposed between a first layer and a second layer, each active region comprising a second phase change material comprising titanium.

The titanium concentration of the second phase change material is advantageously higher than the titanium concentration of the first phase change material and advantageously lower than the titanium concentration of the titanium-based material.

Finally, the invention relates to a method for storing a message in a set of non-initialised resistive memories, each non-initialised resistive memory comprising:
a first layer, comprising a titanium-based material, said titanium-based material being conductive;
a second layer, extending over the first layer and comprising a first phase change material, said first phase change material being able to be doped with titanium;
   the set of non-initialised resistive memories comprising a first sub-set of non-initialised resistive memories and a second sub-set of non-initialised resistive memories, distinct from the first sub-set of non-initialised resistive memories, the storage method comprising a step of initialising each resistive memory of the first sub-set of non-initialised resistive memories by implementing the initialisation method according to the invention, the message stored being formed by the non-initialised resistive memories or by the resistive memories initialised.

Memories initialised by means of a “high” current and non-initialised memories are thus obtained. Initialised memories will be used to be programmed into the wanted state (“SET” or “RESET”) with a write current (also called “programming” current) lower than the initialisation current. Non-initialised memories will be insensitive to the programming current, i.e. they will remain in their “non-initialised” state.

Advantageously, the storage method comprises a step of programming each non-initialised memory of the second subset and each initialised memory of the first subset. Thus the memories, whether initialised or not, store a false message. It is thus more difficult to determine the true message stored in all the memories.

The invention and its different applications will be better understood upon reading the following description and upon examining the accompanying figures.

### BRIEF DESCRIPTION OF THE FIGURES

The figures are set forth byway of indicating and in no way limiting purposes of the invention. Unless otherwise specified, a same element appearing in different figures has a single reference.

FIG. 1, FIG. 2, FIG. 3, FIG. 4 schematically represent first, second, third and fourth embodiments of a non-initialised resistive memory according to the invention.

FIG. 5 represents a measurement of the resistivity of four layers of titanium alloy with different stoichiometries.

FIG. 6 represents a cumulative distribution of the state of a set of non-initialised resistive memories according to the invention as a function of resistance.

FIG. 7 represents the variation in resistivity as a function of temperature for three layers of titanium alloy with different stoichiometries.

FIG. 8 and FIG. 9 schematically represent a first and a second embodiment of an initialised resistive memory obtained at the end of implementation of an initialisation method according to the invention.

FIG. 10 schematically represents a dilution rate of a titanium-based material in an active region of a resistive memory obtained at the end of an initialisation method according to the invention, as a function of a dimension of this active region.

FIG. 11 schematically represents a mode of implementation of an initialisation method according to the invention.

FIG. 12 schematically represents a step in the initialisation method according to the invention.

FIG. 13 schematically represents a measurement of the resistance of a resistive memory according to the invention during and after the initialisation method.

FIG. 14, FIG. 15, FIG. 16 schematically represent a measurement of the resistance of two resistive memories according to the invention as a function of an applied current and a duration of current application.

FIG. 17 schematically represents one mode of implementation of a storage method according to the invention.

### DETAILED DESCRIPTION

The aim of the invention is to provide a resistive memory whose performance and, more particularly, its write rate or retention level are configured (also referred to as initialised).

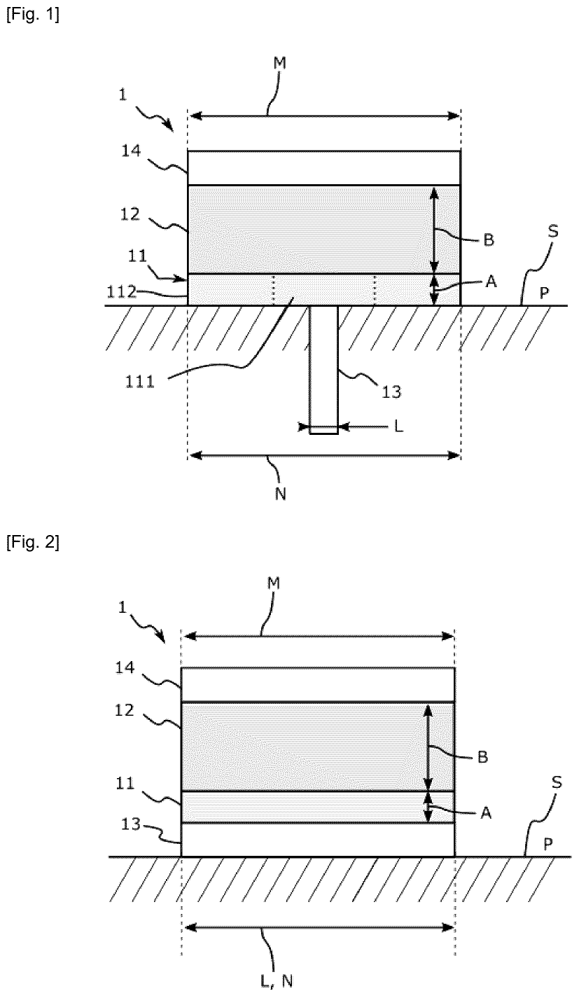

The invention relates especially to a method for initialising a so-called “non-initialised” memory. FIG. 1, FIG. 2, FIG. 3 and FIG. 4 schematically represent, in a cross-sectional view, a non-initialised resistive memory 1 (also referred to as a memory) implemented by said method of the invention. Said non-initialised resistive memory comprises at least one first layer 11 and at least one second layer 12. In these embodiments, the memory 1 also comprises a first electrode 13 and a second electrode 14, said first and second electrodes 13, 14 being separated by each first and second layer 11, 12.

In FIG. 1 and FIG. 2, the first layer is disposed on the first electrode 13. The second electrode is disposed on the second layer 12. The second layer 12 extends over the first layer 11.

In FIG. 3, the memory 1 comprises alternating first and second layers 11, 12. One of the first layers 11 is disposed on the first electrode 13. The second electrode is disposed on one of the second layers 12. In this alternation, each second layer 12 extends over one of the first layers 11.

In FIG. 4, the memory 1 comprises two second layers 12 and a first layer 11. Each second layer 12 extends over one of the faces of the first layer 11. A second layer 12 extends over the bottom electrode 13, in contact therewith. The first layer 11 then extends over the second layer 12 which is in contact with the electrode 13.

In common with the embodiments of FIG. 1, FIG. 2, FIG. 3 and FIG. 4, each first layer 11 comprises a titanium-based material. The titanium-based material is electrically conductive. For example, it has a resistivity of less than 1000 μΩ·cm and advantageously less than or equal to 700 μΩ·cm. The low resistivity of the titanium-based material improves the progressiveness of the initialisation of memory 1 (i.e. the configuration of its performance, as described below) and therefore its control. Conversely, an alloy with insulating properties makes it difficult to control the initialisation of memory 1. Indeed, an alloy with insulating properties requires a breakdown voltage which can be high and can degrade memory 1 during its initialisation. It is therefore preferable to avoid them.

In common with the embodiments of FIG. 1, FIG. 2, FIG. 3 and FIG. 4, each second layer 12 comprises a first phase change material. By phase change material, it is meant a material that can have an amorphous phase or a crystalline phase according to its thermal history. These are preferably solid phases that are stable over a temperature range that can be extended around room temperature. The phase change materials considered in an information storage context are those with a measurable difference in resistivity between the amorphous and crystalline phases. The difference in resistivity between both phases is, for example, 300% or more. An amorphous phase generally has a higher resistivity than a crystalline phase. Thus, encoding information in the resistance of the first phase change material of each second layer 12 amounts to modifying the phase in which the latter is located.

The difference in resistivity between the crystalline and amorphous phases is selected so that it can be easily measured, making it possible to determine the information stored in the non-initialised memory. In binary representation, a low resistance (and therefore high conductance) state of the first phase change material is referred to as a high state, corresponding for example to a crystalline phase of said first material. A high resistance (low conductance) state of the first phase change material is then referred to as a low state, corresponding for example to an amorphous phase of said first material.

The change of phase, and therefore of resistivity, in a second layer 12 may be induced by circulating a pulse of electric current which locally heats the first phase change material. According to the amplitude and form of the electrical current pulse, the first phase change material of said second layer 12 performs either:
quenching in the amorphous phase; or
crystallisation in the crystalline phase.

By pulse shape, it is meant the variation in current amplitude over time. For example, a so-called “rectangular” pulse may have a current rise to a maximum amplitude for a first duration, holding this maximum amplitude for a second duration and then descent or fall to zero current for a third duration.

The maximum amplitude of the current enables the first phase change material to be heated to a temperature that allows the phase change to take place. The holding time and fall time have an impact on the cooling rate of the phase change material, for example, and can therefore induce quenching or crystallisation of the first phase change material. For example, a high holding time and a high fall time allow crystallisation of the first phase change material, while a low holding time and a low fall time allow quenching of the first phase change material.

By “crystallisation rate”, it will be meant the reciprocal of the time taken to crystallise the first phase change material. By “quenching rate”, it will be meant the reciprocal of the time required to quench the first phase change material.

By “transition temperature”, it will be meant the temperature required to crystallise or quench the first phase change material in the second layer. The transition temperature is to be distinguished from a “melting temperature” at which the first phase change material, initially solid, melts. The transition temperature corresponds to an electric current to be applied to heat the first phase change material and then allow it to crystallise or quench. In addition, the higher the electric current, the greater the amount of the first phase change material likely to undergo crystallisation or quenching.

The rate of crystallisation of the resistive memory is limited to the amplitude of the current required to reach the transition temperature. It may also be limited by the physical crystallisation process itself. The quenching rate of the resistive memory is also limited in the same way.

The initialisation method makes it possible to modify crystallisation and quenching rates of the non-initialised memory 1 by adding titanium to the first phase change material. For this, the first phase change material is expected to be able to be doped by means of titanium. Indeed, some additional elements such as titanium, that will be called dopants, combined with some phase change materials, modify the transition temperature and the crystallisation and/or quenching rates of these phase change materials. Said transition temperature then tends to decrease while the crystallisation and/or quenching rates tend to increase. The combination of titanium with the first phase change material (following initialisation of the memory) therefore makes it possible to reduce the current to be applied to crystallise or quench said material, for increasing the rate at which information is written to the resistive memory.

While the addition of titanium to the first material increases crystallisation and quenching rates, it reduces the level of memory retention.

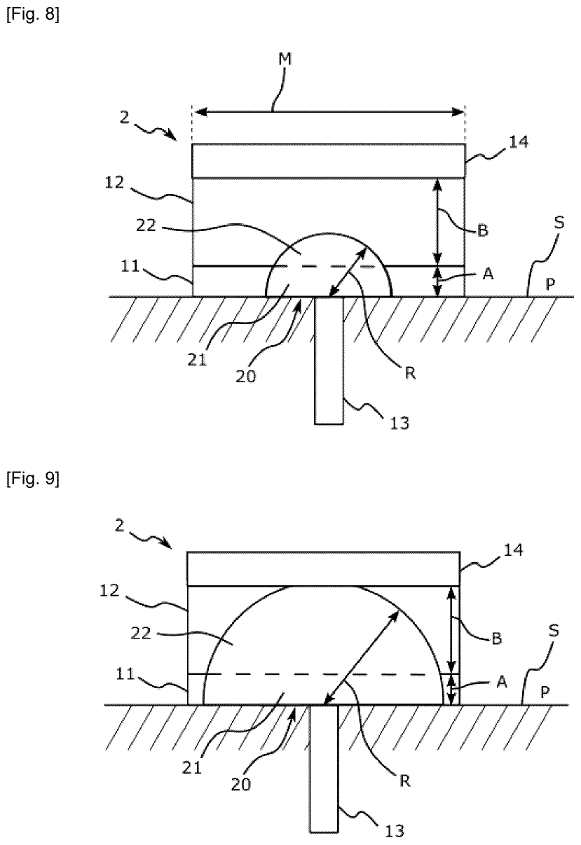

In the non-initialised resistive memory 1, the first phase change material is free of titanium and said memory 1 has a high retention level. When the resistive memory 1 is initialised (principles and methods described with reference to FIG. 8 to FIG. 15), the first material contains titanium and said memory 1 has a high crystallisation and/or quenching rate. Each first layer 11 of the memory 1 then acts as a titanium tank so that the performance (retention level or operating rate) of the resistive memory 1 can be modified. It is advantageous that the first phase change material is selected for its ability to be doped by means of titanium.

Finally, to improve the doping phenomenon, it is advantageous for the titanium-based material and the first phase change material to be easily miscible together when molten. In this way, the phase change material resulting from the mixture of these two materials has good structural and electronic homogeneity.

FIG. 1 schematically represents, in a cross-sectional view, a first embodiment of the non-initialised resistive memory 1. In this embodiment, the memory 1 comprises only a first layer 11 and a second layer 12. The first and second electrodes 13, 14 are separated by the first layer 11 and the second layer 12. The first layer 11 is in contact with the first electrode 13 and is electrically connected thereto. The second layer 12 is in contact with the first layer 11 and is electrically connected thereto. The second electrode 14 is in contact with the second layer 12 and is electrically connected thereto. The first and second electrodes 13, 14 as well as the first and second layers 11, 12 are thus electrically connected in series so that an electric current can circulate between both electrodes 13, 14 and through the first and second layers 11, 12.

The first layer 11 extends for example over an insulating substrate S, comprising for example a dielectric material. The plane of the layers P then corresponds to the surface of the insulating substrate S. The first layer 11 has a thickness A of between 0.5 nm and 20 nm. The thickness A of the first layer is measured perpendicularly to the plane of the layers P. The second layer 12 extends over the first layer 11, i.e. parallel to the plane of the layers P. The second layer 12 has a thickness B, measured perpendicularly to the plane of the layers P. It can be between 10 nm and 200 nm. The thickness B of the second layer 12 is advantageously greater than the thickness A of the first layer 11 and preferably greater than four times, or even twenty times, the thickness A of the first layer 11.

It is advisable to ensure that the thickness B of the second layer is large enough to provide sufficient thermal insulation for the second electrode 14. Good insulation reduces the amplitude of the current required to program memory 1. A thickness B of the second layer of about 50 nm provides sufficient insulation. On the other hand, it is preferable to avoid this thickness B being too great as it can make it difficult to integrate memory 1.

In the embodiment of FIG. 1, the first electrode 13, also referred to as the “bottom” electrode, is oriented perpendicularly to the plane of the layers P. It passes through the substrate S, for example, in the same way as a conductive via, to emerge at the surface of said substrate S. It can also be disposed in a trench provided in the substrate S and disposed under the first layer 11. The first layer 11 then extends in contact with the substrate S and the first electrode 13. The first layer 11 is thus electrically connected to the first electrode 13.

The first layer 11 may have a width N of between 50 nm and 300 nm. It may also have a depth (not shown in FIG. 1 to FIG. 4 because it is perpendicular to the sectional planes) of between 50 nm and 300 nm.

The bottom electrode 13 has a width L, measured in parallel to the plane of the layers P. The width L of the bottom electrode 13 is advantageously less than the width N (or depth) of the first layer 11. In this way, the first electrode 13 can be in contact with a central portion 111 of the first layer 11. By central portion 111, it is meant a portion of the first layer 11 remote from the flank 112 of said first layer 11. Contact of the first electrode 13 with a central portion 111 of the first layer 11 facilitates initialisation of the memory 1, as described below. The width L of the bottom electrode 13 is, for example, between 1 nm and 50 nm.

The bottom electrode 13 can also have a depth (also not shown in FIG. 1 to FIG. 4 because it is perpendicular to the sectional planes) advantageously between 50 nm and 300 nm.

According to one preferred implementation, the first layer has a width×depth equal to 300×300 nm. The bottom electrode 13 then has a width×depth equal to 5×50 nm.

The second electrode 14, which may also be referred to as the “top” electrode, extends directly in contact with the second layer 12, in parallel to the plane of the layers P. The second electrode 14 has a width M, substantially equal to the width N of the first layer 11. It may also have a depth substantially equal to the depth of the first layer 11. The second electrode 14 is therefore wider than the bottom electrode 13.

By substantially equal, it is meant equal to within 20%, or even advantageously to within 10%. The advantage of substantially equal dimensions is that they simplify manufacturing steps (such as delimiting memory 1).

A memory 1 according to the embodiment of FIG. 1 can be produced by successively forming the first layer 11, the second layer 12 and the top electrode 14 from the substrate S and the bottom electrode 13 (which is already integrated into the substrate S). The thickness of the top electrode 14 is advantageously between 10 nm and 100 nm. The memory 1 is then delimited by means of etching. Viewed from above, the memory 1 may be circular or rectangular in shape. The memory 1 is advantageously delimited by placing the central portion 111 of the first layer 11 vertically above the bottom electrode 13.

The first and second layers 11, 12 can be produced by Physical Vapour Deposition (PVD) and/or Chemical Vapour Deposition (CVD) and/or Atomic Layer Deposition (ALD). The bottom and top electrodes 13, 14 can also be formed by PVD or CVD an for example from TiN.

FIG. 2 schematically represents, in a cross-sectional view, a second embodiment of memory 1. Unlike the embodiment of FIG. 1, the bottom electrode 13 does not pass through the insulating substrate S but extends over the same and is therefore parallel to the plane of the layers P. The first layer 11 then extends along its entire length in contact with the bottom electrode 13. The width L of the first electrode 13 is equal to that of the first layer 11 and the top electrode 14. The depths of the bottom electrode 13 and the first layer 11 are then substantially equal. There is therefore no central portion of the first layer 11 in this embodiment.

The manufacture of a memory 1 according to the embodiment of FIG. 2 differs from the manufacture previously described in that the bottom electrode 13 is deposited before the first layer 11, for example directly onto the substrate S. The delimitation of the memory 1 also differs in that it can delimit the entire memory 1 at the same time, especially comprising the delimitation of the bottom electrode 13.

FIG. 3 schematically represents, in a cross-sectional view, a third embodiment of the memory 1. Unlike the embodiment of FIG. 1, the memory 1 comprises alternating first and second layers 11, 12. Each first layer 11 comprises the titanium-based material. Each second layer 12 comprises the first phase change material. Advantageously, the first layers 11 have the same thickness A to within 20% or even 10%. Similarly, the second layers 12 also advantageously have the same thickness B to within 20% or even 10%.

The alternation of the first and second layers 11, 12 forms of an integer n of bilayers. The alternation is therefore of the type [M1/M2]×n where M1 represents each first layer and M2 represents each second layer. The alternating first and second layers 11, 12 extend between the bottom electrode 13 and the top electrode 14. A first layer 11 extends over the bottom electrode 13, in contact with the latter. The top electrode 14 extends over a second layer 12 of said [M1/M2]×n alternation. In this way, said alternation electrically connects the bottom electrode 13 to the top electrode 14.

FIG. 4 schematically represents, in a cross-sectional view, a fourth embodiment of the non-initialised resistive memory 1. Unlike the embodiment of FIG. 2, the memory 1 comprises two second layers 12. One of the second layers 13 extends, for example, over the bottom electrode 13, in contact therewith. The first layer 11 then extends over this second layer 12. Both second layers 12 have substantially the same thickness B (measured perpendicularly to the plane of the layers). In this embodiment, the first layer 11 is no longer in direct contact with the bottom electrode 13 but is electrically connected thereto via one of the second layers 12. Advantageously, the second layers 12 comprise the same first phase change material.

In this embodiment, the bottom and top electrodes 13, 14 each have a width L, M equal to the width N of the first layer. In a further development of this embodiment, the bottom and top electrodes 13, 14 have a width L, M greater than or equal to the width N of the first layer. The same applies to the depths of the bottom and top electrodes 13, 14 and the first layer 11. Both second layers 12 also have the same width N and depth as the first layer 11.

In common with the embodiments of FIG. 1, FIG. 2, FIG. 3 and FIG. 4, the first phase change material may comprise a binary alloy or a ternary alloy. Each element of said alloy then preferably belongs to one of the groups of elements IIIB, IVB, VB or VIB of the periodic table of elements. These groups comprise, for example, the elements Ga, Ge, Sb, Te and Se. The first phase change material can therefore be GeSbTe, GeSb, GeTe or SbTe. Each element in said binary or ternary alloy is preferably a metalloid, comprising, for example, Ge, Sb and Te. It is also preferentially a “stoichiometric” alloy in that the stoichiometric coefficients of each constituent (e.g. Ge, Sb and Te) are natural integers.

In a preferred embodiment, the first phase change material is a chalcogenide and in particular a ternary alloy of the type GeₓSb_{y}Te_{z} (where x, y, and z are stoichiometric coefficients). The first chalcogenide material can have a stoichiometry {x, y, z}={2, 2, 5} and therefore forms of Ge₂Sb₂Te₅. This particular alloy is referred to as “GST225”. Other alloys of the GeₓSb_{y}Te_{z} type can be used, such as GeTe, Sb₂Te₃, Ge₁Sb₂Te₄ (referred to as “GST124”) or Ge₁Sb₄Te₇ (referred to as “GST147”).

The first phase change material of the second layer 12 may also comprise traces, intentional or unintentional, of an element which has an influence on the electronic behaviour of the first phase change material. For example, these are traces of carbon or nitrogen.

In common with the embodiments of FIG. 1, FIG. 2, FIG. 3 and FIG. 4, each first layer 11 comprises a titanium-based material. Each first layer 11 then acts as a titanium tank which can be mixed with the first phase change material of each second layer 12. Mixing the titanium from the first layer with some of the first phase change material thus makes it possible to form a second phase change material, which has a higher switching rate than the first phase change material.

The titanium-based material may comprise a first element complementary to titanium, referred to as the “carrier element”. The carrier element is preferably neutral with respect to electronic properties of the first phase change material. It may be one of the elements of the first phase change material, for example belonging to one of the groups of elements IIIB, IVB, VB or VIB of the periodic table of elements. For example, the titanium-based material may be TiTe, TiGe or TiSb. Where the first phase change material is a ternary “GST” alloy, the element may be tellurium Te, in which case the titanium-based material is the alloy Tiₚ Te_{q} (where p and q are mixing coefficients of the elements in atomic percent). Said titanium-based material may also comprise one or more other carrier elements. For example, when the first phase change material is a GST, said titanium-based material may be the alloy TiSbTe.

The titanium-based material may also comprise impurities. The impurities are preferably active with respect to electronic properties of the first phase change material. They may be nitrogen or carbon, in which case the titanium-based material of the first layer 11 may be a TiₚCᵣ alloy or a TiₚNᵣ alloy (where r is also a mixture coefficient in atomic percentage).

The titanium-based material may also comprise a carrier element and impurities as previously described. Said material may therefore be in the form of TiₚTe_{q}Cᵣ or TiₚTe_{q}Nᵣ.

The conductive nature of the titanium-based material makes it easier to configure performance of the resistive memory and improves the reproducibility of the configuration on a set of resistive memories according to the invention.

Preferably, the resistivity of the titanium-based material of each first layer 11 is less than 1000 μΩ·cm. The mixture of the elements in the titanium-based material can be adjusted so that the same has a conductive character. For example, the TiTe₂ alloy has a resistivity of about 4000 μΩ·cm, making it a poor candidate for forming a first layer 11. In addition, the TiTe₂ alloy has a semi-metallic character, which can reduce control and reproducibility of the memory performance configuration (resistivity tends to decrease as a function of temperature). The TiTe alloy, on the other hand, has a resistivity of less than 1000 μΩ·cm and may therefore be a good candidate for forming a first layer 11. The closer the resistivity of the titanium-based material of a first layer 11 is to the resistivity of the bottom electrode, the better the reproducibility of the memory performance configuration. Moreover, the resistivity of the titanium-based material of each first layer 11 is advantageously less than 700 μΩ·cm.

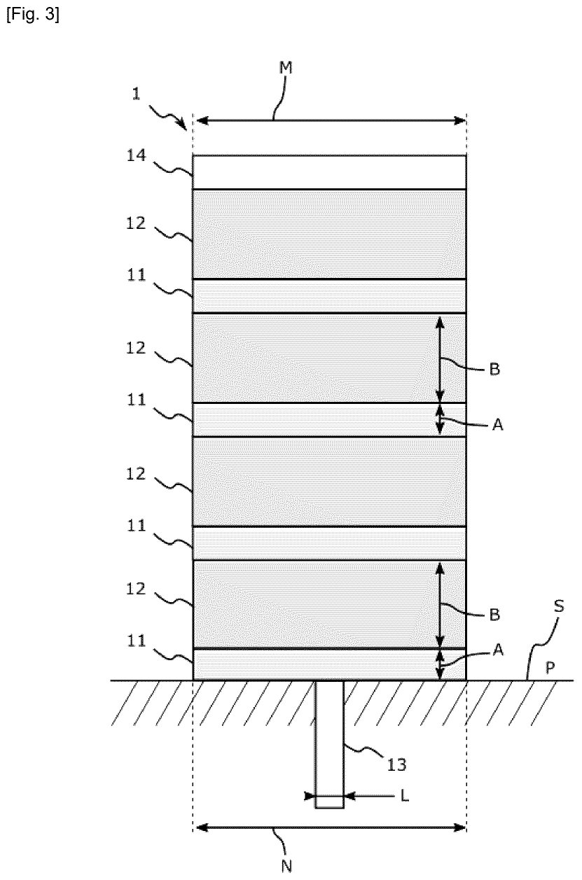

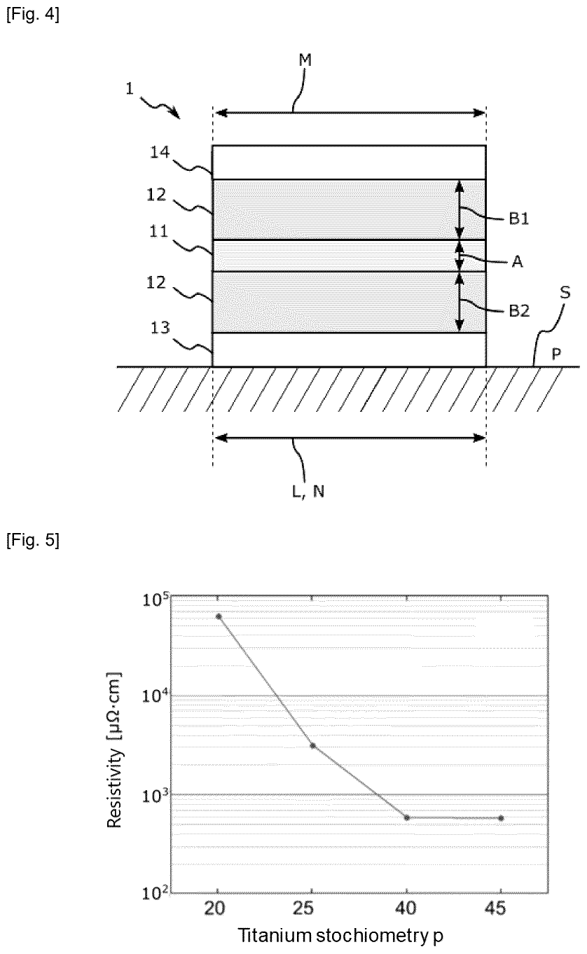

FIG. 5 represents, for example, a measurement of the resistivity of an example of a titanium-based material, once deposited in the form of a thin layer (with a thickness of less than 20 nm), as a function of the atomic percentage of Ti. The titanium-based material considered is the alloy Tiₚ Te_{q} (where q=1−p). Four different atomic percentages p are considered: Ti₂₀Te₈₀; Ti₂₅Te₇₅; Ti₄₀Te₆₀; Ti₄₅Te₅₅. FIG. 5 represents resistivity as a function of the atomic percentage of titanium (that of tellurium can be deduced). The resistivity decreases as the percentage of titanium in the alloy increases. Thus the alloys Ti₄₀Te₆₀ and Ti₄₅Te₅₅ may be good candidates for forming a first layer 11 of the non-initialised resistive memory 1.

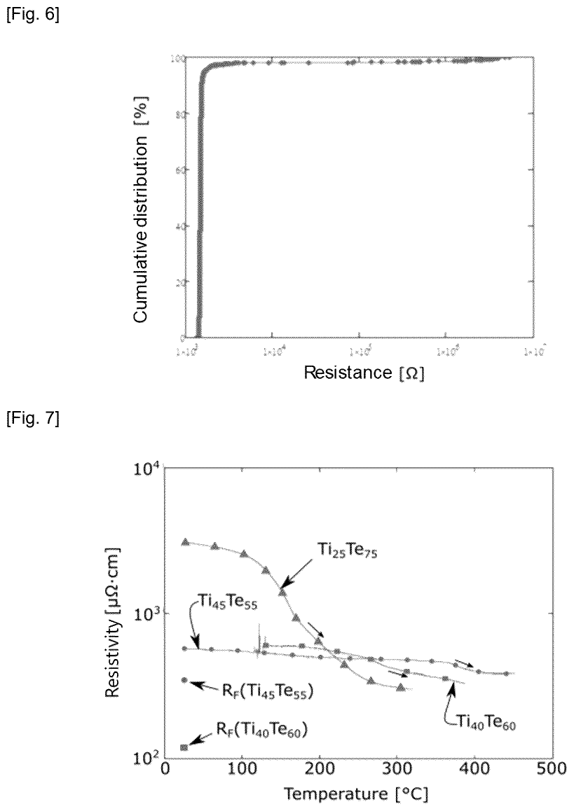

FIG. 6 shows a cumulative distribution of the resistance value of a set of non-initialised resistive memories 1, herein 4096 memories (4 kbytes). Each of the 4096 memories comprises a first layer 11 and a second layer 12 (an embodiment similar to that illustrated in FIG. 1). The first layer 11 of each memory 1 comprises TiTe and the second layer 12 of each memory 1 comprises GST225. The TiTe alloy, by virtue of its metallic nature and especially its low resistivity, has little influence on the behaviour of each memory 1. The cumulative distribution of resistance values thus shows an abrupt transition, indicating that all the memories have similar resistance values. The effect of having a distribution with very little dispersion ensures that memories with very similar morphologies can be initialised. Memories initialised by means of the same initialisation current will therefore show little variability in their behaviour.

The low resistivity of the titanium-based material enables the first layer 11 to act as an electrode and improve distribution of the electric field at the second layer 12. This results in a homogenisation of the behaviour of each non-initialised resistive memory 1, reflected by a cumulative distribution of resistances.

It is also advantageous that the titanium-based material is stable even when subjected to thermal annealing. Indeed, the non-initialised resistive memory 1 can be produced at a logic block of an integrated circuit (“front end of line”). The manufacture of the back end of line can implement one or more annealing processes at temperatures of up to 400° C. It is therefore advantageous for the titanium-based material to retain its electrical properties, such as its conductive nature, after thermal annealing at up to 400° C. In this respect, it is advantageous that the titanium-based material of each first layer 11 and the first phase change material of each second layer 12 then have a melting temperature above 400° C. and preferably above 450° C.

FIG. 7 represents, for example, the variation in resistivity observed in three titanium-based materials, especially TiₚTe_{q} alloys, when annealed at up to 400° C., as well as the final resistivity R_{F} of two of the annealed alloys. The alloys considered are Ti₂₅Te₇₅; Ti₄₀Te₆₀; Ti₄₅Te₅₅. Each curve represents the resistivity as the annealing temperature rises. Each alloy shows a reduction in resistivity as the temperature increases. The reduction in resistivity during annealing is not due to the metallic character of each alloy, which instead shows an increase in resistivity above some temperature. The reduction in resistivity during annealing is due here to the improvement in the crystalline quality of the alloys involved. Two of the alloys considered, Ti₄₀Te₆₀ and Ti₄₅Te₅₅, show a moderate reduction as the temperature rises. The resistivity after annealing R_{F} for both alloys mentioned above is also reported R_{F} (Ti₄₀Te₆₀), R_{F} (Ti₄₅Te₅₅). The post-annealing resistivity Rf of the Ti₂₅Te₇₅ alloy is not reported because its value is outside the ranges considered [10² μΩ·cm; 10⁴ μΩ·cm].

The Ti₄₀Te₆₀ alloy is sufficiently stable after annealing to form a first layer 11 of a non-initialised resistive memory 1. Indeed its resistivity varies by less than 70%. However, the variation in resistivity of the Ti₄₅Te₅₅ alloy after annealing is smaller, as it is less than 40%.

Generally speaking, a conductive alloy with a percentage (or stoichiometry) of titanium of between 40% and 50% is an acceptable candidate for forming a first layer 11. However, a titanium percentage of 45% is preferred.

A second phase change material can be formed by mixing the titanium based material molten with the first phase change material molten. A good miscibility of the titanium-based material with the first phase change material when these are molten moreover makes it possible to form a second homogeneous phase change material. The second phase change material is in particular in that it comprises titanium. Titanium especially comes from the at least partially dissociating titanium-based material. By dissociation, it is meant that the chemical bonds of some of the constituents of said titanium-based material are broken, especially as a result of temperature. The second phase change material therefore comprises first phase change material doped with titanium from the titanium-based material. At least one region 20, referred to as the “active region”, is formed by the second phase change material.

FIG. 8 and FIG. 9 schematically represent, in a cross-sectional view, two embodiments of a so-called “initialised” resistive memory 2, obtained after implementation of the initialisation method according to the invention (described below), i.e. comprising at least one active region 20. An initialised memory 2 is a memory whose performance has been configured. Each active region 20 can be obtained by circulating an electric current through the first and second layers 11, 12. The electric current then heats said layers 11, 12, especially by Joule effect, and a thermal gradient is established within the initialised memory. When the electric current reaches a threshold, the temperature within the first and second layers 11, 12 is such that each of them fuses, at least in part, creating one or more volumes (or bubbles) of material molten therewithin. The percolation of the volumes of molten material through the thickness of each first layer and at the interface between the first and second layers makes it possible to form a volume in which titanium-based material and first phase change material mix and combine. Solidification of said volume thus forms at least one active region 20, comprising at least some of the second phase change material (i.e. the first phase change material doped with a concentration of titanium).

The miscibility of the titanium-based material with the first phase change material allows both materials to form of a homogeneous volume of molten material which will form of, upon solidification, an active region 20. In addition, the ability of the titanium of the titanium-based material to combine with the first phase change material thus enables a second phase change material to be formed by which the electrical properties are different to those of the first phase change material. An active region 20 can store information, i.e. switch from a low resistivity state to a high resistivity state.) By virtue of titanium, the crystallisation rate of the second phase change material is increased relative to the crystallisation rate of the first phase change material (without titanium). As a result, the rate of switching to a high or low resistivity state is higher.

The switching rate of an active region 20 is therefore higher than the switching rate of a second layer (or of the non-initialised memory 1 overall). In addition, the switching current of the active region (enabling the second material to be heated to its transition temperature) is lower than the switching current of a second layer 12. An active region 20 can therefore be switched without switching a second layer 12.

Titanium in the titanium-based material may be able to spontaneously combine with the first phase change material, for example by insertion, without necessarily requiring dissociation of the alloy. Combination of the titanium with the first phase change material may, however, require dissociation of part of the titanium-based material, for example so that titanium atoms can combine by insertion or substitution with the first material.

The bond strengths within the titanium-based material may be sufficiently weak that, when molten, the material partially dissociates and releases titanium atoms. The binding energy of titanium within its material is, for example, selected so that it is less than or equal to the latent heat of liquefaction of the first phase change material. In this way, when sufficient energy is supplied to the non-initialised memory 1 to melt the first phase change material, part of the titanium-based material is dissociated, leaving free titanium atoms.

Dissociation of the titanium-based material can also be achieved by means of additional heating, obtained by means of an electrical pulse. The amplitude of the electrical pulse used to dissociate the titanium-based material is advantageously less than or equal to the amplitude of an initialisation current (described hereinafter) allowing the titanium-based material and the first phase change material to melt. The amplitude of the electrical pulse is preferably less than 100 mA, so as not to degrade the materials in the non-initialised memory 1. Preferably, an amplitude of less than 10 mA, or even less than or equal to 5 mA, is sufficient. The duration of the electrical pulse is preferably less than 10 μs or even less than 1 μs, and even more preferably less than 500 ns.

Each active region 20 is disposed between the top and bottom electrodes 14, 13. In the embodiments of FIG. 8 and FIG. 9, an active region 20 has a hemispherical (dome) shape having radius R. Its base is parallel to the plane of the layers P and coincides with the surface of the substrate S. The first layer 11 and the active region 20 also lie in the same plane.

When the bottom electrode 13 passes through the substrate S, as is the case in FIG. 8 and FIG. 9, the active region 20 is disposed in vertical alignment with the bottom electrode 13 and against this electrode. Moreover, by virtue of its formation mechanism, the active region 20 is located at its contact zone with the bottom electrode 13. The radius R of the active region 20 is advantageously greater than the thickness A of the first layer 11 (in order to allow mixing of the titanium-based material with the first material). In the example of FIG. 8, the radius R is less than the total thickness A+B of the first and second layers 11, 12.

In the example of FIG. 9, the radius R is greater than the total thickness A+B of the first and second layers 11, 12. In the latter case, the active region 20 connects the bottom and top electrodes 13, 14 to each other.

In these two examples, the first layer 11 differs from the non-initialised memory 1 in that it surrounds a portion 21 of the active region 20 (i.e. the latter passes right through it from one side to the other) referred to as the “lower dome portion”. In other words, the active region 20 passes through the first layer 11. By virtue of this, the read and/or programming currents preferentially pass through the active region 20, so that electrical conduction in the active region 20 is little influenced by the remaining first layer 11.

The second layer 12 of the initialised memory 2 also differs from memory 1 in that it also surrounds a portion 22 of the active region 20, referred to as the “upper dome portion”.

Upon applying a current between the bottom and top electrodes 13, 14 of the non-initialised resistive memory 1, said current circulates through the first layer 11 and the second layer 12. The heating in each layer depends on the current density at each point of said layers 11, 12. The through bottom electrode 13, as illustrated in FIG. 1, FIG. 3, FIG. 8 and FIG. 9, concentrates electric current at the point of contact between said bottom electrode 13 and a first layer 11 and more particularly at a central portion 111 of a first layer 11. The current density is concentrated at the central portion 111 and in the vicinity of this portion 111. Iso-density curves may have a substantially hemispherical shape from the bottom electrode 13. The current density, when it exceeds a critical density, causes the materials to melt and creates a volume of molten materials. The interface between the solid and liquid media (i.e. the surface of the volume of molten material) also follows the iso-density curves and may also have a substantially hemispherical shape from the bottom electrode 13.

According to the amplitude of the current applied between the bottom and top electrodes 13, 14, the surface of the volume of molten material can reach the second layer 12. Some of the titanium atoms in the titanium-based material then combine with the phase change material to form of the second phase change material, which has different electrical properties to the first phase change material. The solidification of the volume of molten material (for example, following the current shut-down) completes the formation of the active region 20 as illustrated in FIG. 8 and FIG. 9.

The active region 20 thus has a second, solidified phase change material containing titanium. Said titanium, for example, forms a new alloy with the first phase change material.

The active region 20 thus makes it possible to store information by encoding it into a resistivity value of the second phase change material. Indeed, the second phase change material in the active region 20 can have an amorphous phase or a crystalline phase in the same way as the first phase change material. On the other hand, titanium combined with the first phase change material tends to increase crystallisation and/or quenching rate of the second phase change material (and therefore switching rate of the active region 20). Thus, the presence of the active region 20, disposed between the bottom and top electrodes 13, 14, makes it possible to store information in the initialised memory 2. Unlike a non-initialised memory 1, the information switching rate is improved.

The second phase change material in the active region 20, illustrated in FIG. 8 and FIG. 9, comprises a volume of the first layer 11 corresponding to the lower portion 21 of the active region 20 and a volume of the second layer 12 corresponding to the upper portion 22 of the active region 20.

The second phase change material has a concentration of titanium. Said titanium concentration is proportional to a dilution ratio of the titanium-based material in the second phase change material. Said dilution ratio is equal to the ratio of the volume of the lower portion 21 of the active region to the total volume of the active region 20. It is therefore dependent on the volume of the active region 20 and therefore on a dimension of the active region 20, such as its radius R. In the example of FIG. 8, the active region 20 has a hemispherical shape and its total dependent volume depends on its radius R. The dilution ratio of the titanium-based material in the active region 20 corresponds to the volume of the lower portion 21 of the active region 20 relative to the total volume of the active region 20. The volume of the lower portion 21 of the active region 20 is given by

$${V}_{21} = {R}^{2} arcsin ( \frac{A}{R} ) + AR \sqrt{1 - {( \frac{A}{R} )}^{2}}$$

Thus, the dilution ratio D of the titanium-based material in the first phase change material is equal to

$$D = \frac{2}{π} arcsin ( \frac{A}{R} ) + \frac{2 A}{π} \sqrt{1 - {( \frac{A}{R} )}^{2}}$$

The dilution ratio D therefore depends directly on the ratio of the thickness A of the first layer 11 to the dimension of the active region 20, herein its radius R.

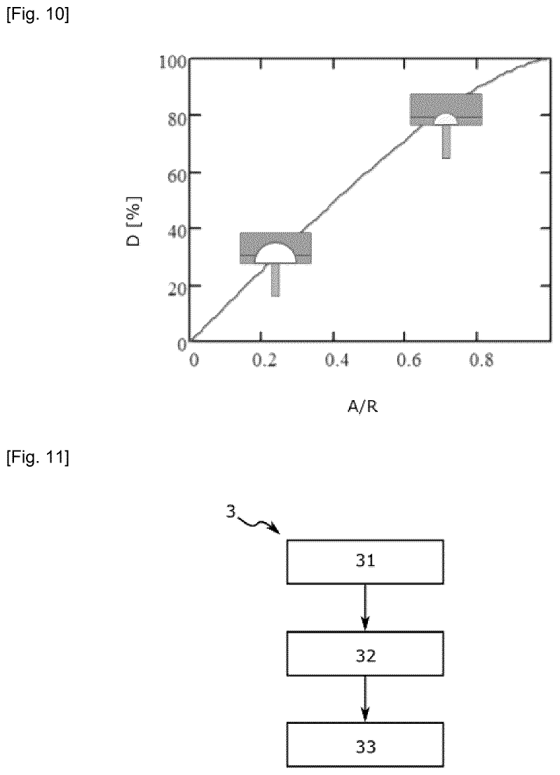

FIG. 10 illustrates the variation of the dilution ratio D of the titanium-based material in the first phase change material, as calculated above as a function of the A/R ratio. The larger the radius of the active region 20 (lower A/R ratio), the more the titanium-based material is diluted in an amount of the first phase change material. Conversely, the smaller the radius of the active region 20 (larger the A/R ratio), the more concentrated the titanium-based material. The non-initialised memory 1 considered for this calculation has an infinite thickness B of the second layer (enabling an A/R ratio of 0 and a value [0; 0] to be obtained).

As a result, an active region 20 with a large dimension has a second phase change material with a low concentration of titanium. Conversely, a small active region 20 has a second phase change material with a high concentration of titanium. A small active region 20 therefore has a high crystallisation and/or quenching rate (since the properties of the phase change material are strongly impacted) whereas a large active region 20 has a low crystallisation and/or quenching rate.

The dimension of the active region 20 depends on the dimension of the total volume of molten material. The latter depends on the parameters leading to its formation, such as the current density in each layer. Indeed, a moderate current density will create a small volume of molten material, whereas a high current density will create a large volume. The current density in the first and second layers 11, 12 is proportional to the amplitude of current applied to these layers. It is therefore by controlling amplitude of the current applied that it is possible to control the dimension of the active region 20. Controlling the amplitude of the current therefore makes it possible to control the rate of dilution of the titanium-based material in the active region 20. Thus, controlling the amplitude of the current makes it possible to control concentration of titanium in the second phase change material.

It is advantageous for the first layer 11 to have a thickness A less than the thickness B of the second layer 12. Thus dilution of the titanium-based material in the first material is more effective. The thickness B of the second layer 12 is, for example, four times greater, or even twenty times greater, than the thickness A of the first layer 11. When the thickness A of the first layer 11 is greater than the thickness B of the second layer B, the variation in the concentration of titanium as a function of a dimension of the active region is smaller. This can improve control of the titanium concentration when the initialisation current is difficult to control. On the other hand, the greater the thickness A of the first layer 11, the greater the minimum size of the active region to allow dilution of the titanium-based material. The minimum current to be applied to form the active region 20 is therefore also higher.

Dilution of the titanium-based material is also effectively achieved when the first phase change material in the second layer 12 comprises an initial concentration of titanium (i.e. before mixing) which is less than the initial concentration of titanium in the titanium-based material in the first layer 11. Thus, melting and mixing of both materials (first material and titanium-based material) tends to dilute rather than concentrate titanium. The first phase change material of the second layer 12 comprises, for example, a zero concentration of titanium.

FIG. 11 schematically represents a method 3 for initialising a memory 1. Implementation of this method makes it possible to obtain an initialised resistive memory 2 as illustrated in FIG. 8 or FIG. 9. The initialisation method 3 comprises a step of circulating 32 an electric current, referred to as the initialisation current, between the first and second electrodes 13, 14 of the resistive memory 1 so as to form the active region 20. The initialisation current being selected so as to fuse part of the titanium-based material of the first layer 11 of the resistive memory 1 and part of the first phase change material of the second layer 12 of the non-initialised resistive memory 1. There follows mechanically a mixture of the molten materials; and a doping of the first fused material with titanium so as to form the second phase change material.

Melting is especially made possible by the establishment of a thermal gradient in the first and second layers 11, 12.

The initialisation method 3 also comprises a step 33 of solidifying the second phase change material to form the active region 20. Solidification 33 is achieved, for example, by shutting down the initialisation current.

Mixing the molten materials and combining the titanium with the first material can take place concomitantly throughout the duration of the initialisation current.

To ensure that the initialisation current used is not too high and does not degrade the memory 1, it is advantageous for melting temperature of the first and second layers 11, 12 to be less than 1000° C. and even more preferably less than 700° C.

The initialisation method 3, as illustrated in FIG. 11, may also comprise a preliminary step 31 of determining the initialisation current. The initialisation current is, for example, comprised between two extreme currents.

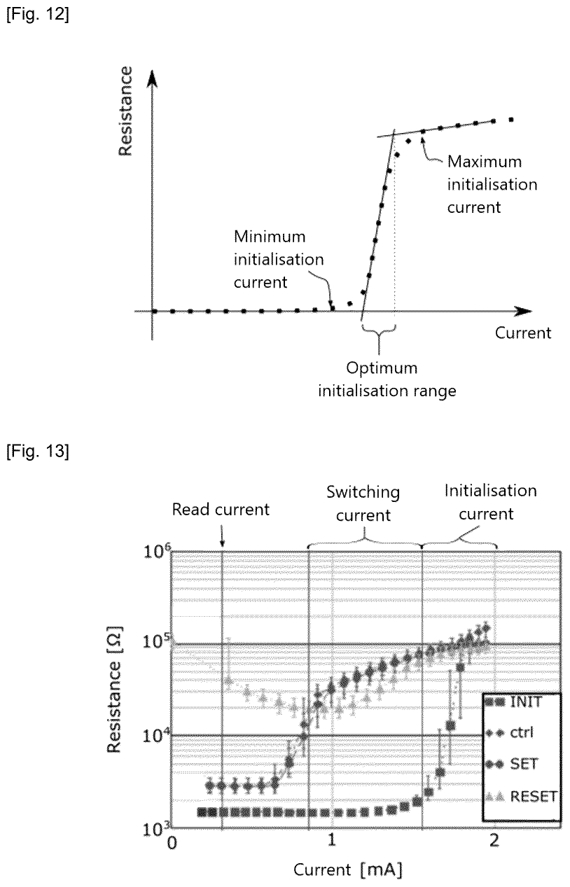

One implementation of the determination step 31 is illustrated in FIG. 12. It implements, for example, a non-initialised so-called “sacrificial” resistive memory because the initialisation of this memory is carried out above the extreme currents (in order to be able to determine said currents).

FIG. 12 schematically shows a resistance curve that can be measured across the sacrificial memory as a function of the current applied.

The resistance shows an initial plateau at low current until the current applied reaches a current referred to as the “minimum initialisation current”. From this minimum current, the resistance curve shows a first bend. The resistance curve also has a zone in which the variation has a continuous slope before having a second bend until a current referred to as the “maximum initialisation current” is reached. The resistance curve then shows a plateau, which may have a slight or decreasing slope. Beyond the second bend, the curve may also show a drop in resistance when the active region 20 connects the bottom and top electrodes 13, 14 together.

Melting materials has little influence on the resistance measurement across the memory. Indeed, as long as the materials remain pure, they do not cause any change in the trend of the resistance curve. The first bend therefore corresponds to the mixture of the titanium-based material in the first layer 11 with the first phase change material in the second layer 12. The initialisation current is therefore selected to be greater than or equal to the minimum initialisation current, so that a molten volume mixing the titanium-based material and the first phase change material can be created. The minimum initialisation current indicates that the volume of molten material has a dimension greater than the thickness A of the first layer 11. The first bend corresponds, for example, to the portion of the curve in FIG. 10 observable at an A/R ratio greater than 0.8 and also comprising a bend.

As the current increases, the dimension of the volume of molten material increases, diluting the titanium-based material by as much. The linear variation in resistance thus provides smoothness and good control over the size of the molten volume (and therefore the dilution of the titanium-based material). This is an optimum initialisation range in which it may be sensible to select the initialisation current.

The second bend occurs when the mechanism reaches saturation. On the one hand, the dilution of the titanium-based material may be high and the increase in the volume of molten material dilutes the titanium-based material less effectively. On the other hand, the increase in the volume of molten material may show saturation, because it has reached a limit to its expansion, such as the flanks of the first and/or second layers 11, 12 or one of the electrodes 13, 14.

Determining 31 the minimum and maximum initialisation currents can be split into two sub-steps corresponding to the determination of a minimum and maximum initialisation current respectively.

Determining said extreme currents can also be carried out sequentially, by increasing the current in steps, wherein said steps can be spaced apart by a period during which no current is applied, allowing, for example, cooling and solidification of the active region 20.

Determining 31 the minimum and maximum initialisation currents can also be carried out by analysing the composition of the active region 20. A series of memories 1 can be initialised by applying different currents (for example arbitrarily). By analysing the composition of each initialised memory 2 and more particularly each active region 20, the minimum and maximum initialisation currents can be determined. For example, it can be expected that the minimum initialisation current makes it possible to form an active region 20 having a maximum concentration of titanium in the second phase change material, this concentration of titanium in the second material being strictly lower than the initial concentration of titanium in the pure titanium-based material (i.e. before mixing) and advantageously strictly higher than the concentration of titanium in the first pure phase change material. It can also be expected that the maximum initialisation current will make it possible to form an active region 20 having a minimum concentration of titanium in the second phase change material, this concentration preferably being less than or equal to 1/100, but advantageously strictly greater than the concentration of titanium in the first pure phase change material.

Applying 32 the initialisation current and solidifying 33 the active region 20 can be carried out sequentially several times. The amplitude of the initialisation current can be increased each time, for example. Thus the dimension of the active region 20 increases each time the initialisation current is applied. This mode of implementation makes it possible to gradually achieve the desired performance. On the other hand, the active region 20 formation mode does not allow the memory to be initialised by applying an initialisation current whose amplitude is less than an amplitude already used.

Moreover, applying a current higher than the initialisation current used to initialise a memory 2 may result in additional initialisation of this memory 2. It is therefore advantageous to read or switch the initialised memory with a current lower than that used to perform initialisation. In other words, it is advantageous to initialise memory 2 with an initialisation current greater than or equal to the read current and the switching current in order to avoid undesired complementary initialisation of the memory when it is read or switched.

The memory to be initialised can also be in an intermediate initialisation state. This intermediate initialisation state is obtained, for example, after a first initialisation. The resistive memory in an intermediate initialisation state then has a so-called “intermediate” active region. This intermediate active region comprises, for example, a third phase change material also comprising titanium. This intermediate active region is obtained, for example, by firstly melting the first and second layers. The third intermediate phase change material then has a higher concentration of titanium than the concentration reached in the second phase change material. Circulating 32 an initialisation current also generates a temperature gradient within the intermediate active region involving its melting and mixing the third phase change material with the titanium-based material of the first layer (also partially molten) and with the first phase change material (also partially molten). This results in the formation of a second phase change material from the first phase change material, the titanium-based material and the third phase change material. The active region 20 formed by the second phase change material also has a dimension (such as its radius) greater than a dimension of the intermediate active region.

FIG. 13 represents a measurement of the mean resistance of a set of 4096 non-initialised memories 1 during different modes of use or during their initialisation. The current applied to each of the memories is a pulse having, sequentially, rise of 10 ns to a maximum amplitude, holding of this maximum amplitude for a duration of 300 ns and fall of 10 ns.

A first resistance curve, referred to as the initialisation curve, measured upon initialising 3 each memory, is represented by squares (also indicated by “INIT” in FIG. 13). The initialisation curve partly has the same trend as the curve discussed with reference to FIG. 12. It especially shows a first plateau for low current values (less than 1.3 mA), a first observable bend for a current between 1.3 mA and 1.6 mA and a linear part between 1.6 mA and 1.8 mA. The maximum current applied is the initialisation current. In this example, the initialisation current is 1.8 mA. At the end of initialisation 3 (here comprising a step of circulating 32 the initialisation current and a step of cooling/solidification 33 the second phase change material formed), each resistive memory 1 is initialised and has an active region 20 in which information can be encoded.

A second resistance curve, referred to as the control curve, represented by diamonds (also indicated by “ctrl” in the figure), shows the variation in resistance of each initialised memory 2 on completion of their initialisation, when the current decreases from the initialisation current (1.8 mA) to zero current. The control curve does not show the same trend as the initialisation curve, demonstrating the change in the resistance of each resistive memory.

A third resistance curve represented by circles (also indicated by “SET” in the figure) shows the variation in resistance of each initialised memory 2 as the applied current increases. The third curve is superimposed on the control curve, showing that the memories are stable and have the same behaviour.

The conductive nature of the titanium-based material of the first layer enables controlled initialisation 3 of each resistive memory and thus proper configuration of their performance. Indeed, on the other hand, a first insulating layer does not enable circulating 32 the initialisation current to each memory 1 to be properly controlled. For example, a high voltage needs to be applied across an insulating material to achieve breakdown and enable a sufficient current to circulate to achieve initialisation. However, it becomes difficult to control the current circulating in the memory at the time of breakdown. This operating mode reduces control of initialisation and results in a wide dispersion of performance within all memories 1.

It is additionally advantageous for the first layer 11 to be metallic. Indeed, a material with an insulating, semiconducting or semi-metallic character shows a different temperature dependence from a material with a metallic character. For example, as the temperature increases, the resistivity of a metallic material increases monotonically above some temperature. Thus, as the initialisation current increases and the temperature in the first layer increases, the resistivity of the first layer increases. The metallic nature of the first layer slows down the increase in current and temperature, making it easy to precisely control the initialisation current circulating in the memory. Conversely, as the temperature increases, a material with a semi-metallic character will have its resistivity decreasing from some temperature. Thus, as the initialisation current increases and the temperature increases in the first layer 11, the resistivity of the first layer decreases. The semi-metallic nature of the first layer then accelerates the increase in current and temperature and can lead to runaway so that the initialisation current can form too large an active region, or even degrade the first and/or second layers. The phenomenon is more intense in the case of insulating or semiconductor materials. The high non-linearity of the resistivity of these materials as a function of voltage and temperature further increases the risk of runaway and therefore memory degradation.

The third resistance curve in FIG. 13 shows a characteristic trend in the behaviour of resistive phase change memories in a low resistance state, also referred to as the “high” or “programmed” or “SET” state.

A fourth resistance curve, represented by triangles (also indicated by “RESET” in the figure), shows the change in resistance of each initialised memory 2 after all the memories 2 have been switched to a high resistance state, also referred to as a “low” or “erased” or even “RESET” state. Unlike the third curve, the fourth curve actually shows a characteristic trend in the behaviour of resistive memories in a low state.

FIG. 13 also shows an example of the read current that can be used to read the resistivity state of an initialised memory, as well as a switching current range of the active region 20 of each initialised memory 2. The initialisation current employed is greater than the read current and the maximum switching current.

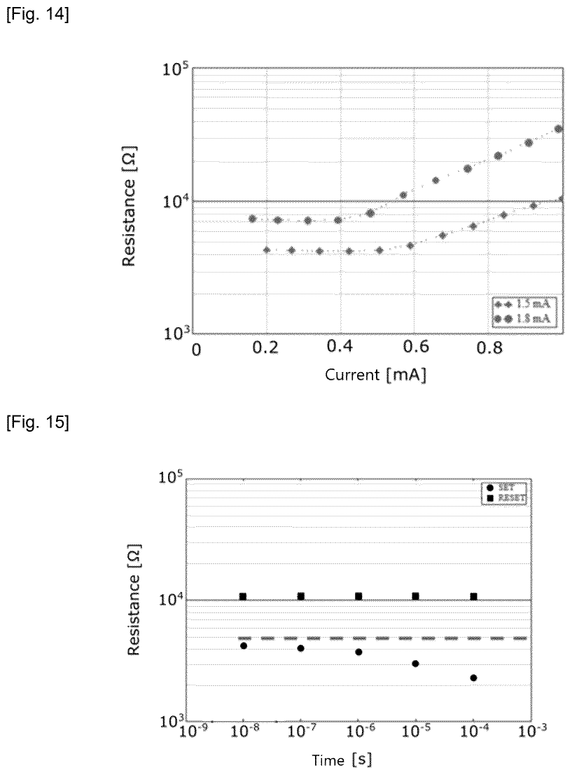

FIG. 14, FIG. 15 and FIG. 16 show the differences in behaviour between two resistive memories 2 initialised by means of two different initialisation currents. A first memory 2 has been initialised by means of an initialisation current of 1.5 mA and a second memory 2 has been initialised by means of an initialisation current of 1.8 mA. Each of the first and second memories 2 therefore comprises an active region 20. However, the active region 20 of the first memory, having been formed by a lower current than the second memory, has a higher concentration of titanium than the active region 20 of the second memory.

FIG. 14 shows two resistance curves as a function of the current applied across both resistive memories 2, when they are in a low resistance state (high or “SET” state). The first memory, initialised with a lesser initialisation current, has a lower resistance than the second memory, initialised with the higher current.

The variation in resistance as a function of current also shows a different slope between both memories, with the first memory (initialised at 1.5 mA) showing a smaller slope than the second memory (initialised at 1.8 mA).

FIG. 15 and FIG. 16 show a measurement of the resistance of both memories when they are in a high-resistance state (referred to as “RESET” in the figures) or in a low-resistance state (referred to as “SET” in the figures), with switching from one state to the other being carried out with different fall times. The fall time corresponds to the time during which the current used to switch decreases to zero. FIG. 15 shows the variation in resistance for the first memory (initialised with an initialisation current of 1.5 mA) while FIG. 16 shows the variation in resistance for the second memory (initialised with an initialisation current of 1.8 mA). The ratio of the resistance value of the high resistance state to the resistance value of the low resistance state is referred to as the “programming window”. Both figures show that the programming window sharply increases as the fall time increases. Increasing the fall time improves crystallisation of the second material in the active region 20 and therefore reduces the associated resistivity (i.e. the programming window). The second memory has a wider programming window than the first memory. However, at equivalent SET resistance (represented by the dotted lines), the first memory requires a fall time of 10 ns whereas the second memory requires a fall time of 10,000 ns.

The first memory, initialised with an initialisation current of 1.5 mA, has a higher switching rate (herein programming rate) than the second memory. The first memory can therefore be used instead of a Static Random Access Memory (SRAM) or a Dynamic Random Access Memory (DRAM). It can be connected to a calculation unit.

Unlike SRAM or DRAM, an initialised resistive memory, whose storage mechanism is based on the ability of the active region to change phase, has low power consumption (as it does not require a continuous power supply to maintain a state), low latency and high integration density.

Conversely, the second memory, initialised with a higher initialisation current, for example 1.8 mA, has a low write rate but offers lower sensitivity to recrystallisation and therefore a better storage level.

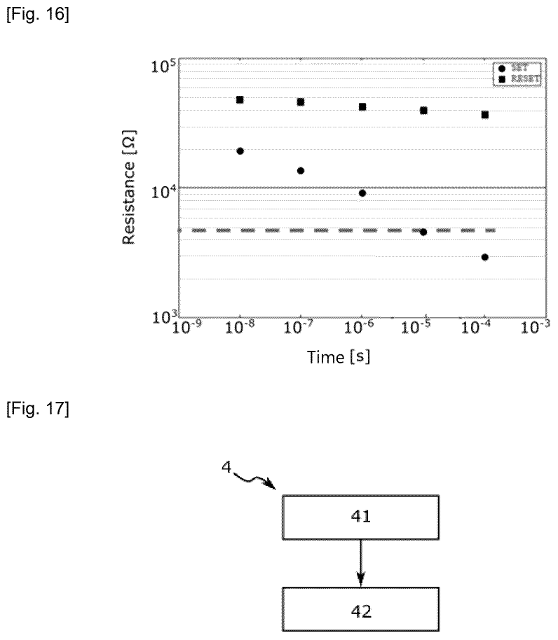

FIG. 17 schematically represents a mode of implementation of a method 4 for storing a message in a set of resistive memories. This storage method uses the ability of the non-initialised memories 1 according to the invention to be initialised to store the message, without however offering easy reading of this message in the absence of an encryption key.

The storage method 4 takes advantage of the small difference in resistivity between an initialised memory and a non-initialised memory when they are in the same resistance state (e.g. high resistance or low resistance). The difference in resistance may be less than 20% or even less than 10%.

For this, the set of non-initialised memories comprises a first sub-set of non-initialised resistive memories according to the invention and a second sub-set of non-initialised resistive memories according to the invention. Both subsets are distinct from each other. That is to say, each of the non-initialised memories in the set exclusively forms part of the first aforementioned sub-set or exclusively of the second aforementioned sub-set.

The storage method 4 comprises a first step 41 of initialising each memory of the first subset by implementing the initialisation method 3 as described previously. Each initialised memory is then, at low current, in an initialised state.

The stored message is then formed by non-initialised memories or initialised memories. The small difference in resistance between an initialised memory and a non-initialised memory in the same resistance state (high or low) makes it impossible to determine which memory carries the information. It is therefore necessary to know the encryption key used to form of the first and second subsets in order to determine the stored message.

As a reminder, a non-initialised or also “virgin” memory is a memory that does not comprise an active region. Conversely, an initialised memory is one that comprises an active region.

The storage method 4 may also comprise a second step 42 consisting in programming, for example randomly, each non-initialised memory of the second sub-set and each initialised memory of the first sub-set. By programming a memory, it is meant switching this memory to a low resistance or high resistance state. Thus the memories, whether initialised or not, store a false message in their respective resistance states, making it possible to hide the true message to be stored in the initialised or non-initialised state. It is thus more difficult to determine the true message stored in all the memories.

Furthermore, without exact knowledge of the parameters used to program the memories of the second subset (such as its amplitude or the crystallisation rate of the devices), it is difficult to force reading the encrypted message by attempting to reprogram each resistive memory in order to distinguish the memories from the programmed memories. Indeed, initialised memories have a lower switching current than the non-initialised memories. Reprogramming all the memories would then tend to erase the stored message rather than reveal it.

1. A resistive memory comprising:
at least one first layer, comprising a titanium-based material, said titanium-based material being conductive;
at least one second layer, extending over said at least one first layer, comprising a first phase change material, said first phase change material being able to be doped with titanium;
a first electrode and a second electrode, the first and second layers separating the first electrode from the second electrode by electrically connecting in series the first electrode to the second electrode, the first electrode being in contact with said at least one first layer or, when there are several first layers, in contact with one of the first layers.

2. The resistive memory according to claim 1, wherein the titanium-based material of each first layer comprises a first element, forming a “carrier element”, which is neutral with respect to switching properties of the first phase change material.

3. The resistive memory according to claim 1, wherein the titanium-based material is to be selected from TiTe, TiGe and TiSb.

4. The resistive memory according to claim 1, wherein a thickness of each second layer is greater than a thickness of each first layer.

5. The resistive memory according to claim 1, wherein the titanium-based material of each first layer comprises impurities capable of influencing electronic properties of the first phase change material.

6. The resistive memory according to claim 1, wherein the titanium-based material has a resistivity of less than 1000 μΩ·cm.

7. The resistive memory according to claim 1, wherein the titanium-based material comprises a titanium concentration such that heat treatment of said titanium-based material at a temperature less than or equal to 400° C. modifies its resistivity by less than 70%.

8. The resistive memory according to claim 1, wherein the first phase change material is a ternary alloy comprising germanium, antimony, tellurium, gallium or selenium.

9. The resistive memory according to claim 1, wherein each of the first and second layers has a melting temperature in the range ]400° C.; 1000° C.[.

10. The resistive memory according to claim 1, wherein at least one part of the titanium-based material of each first layer over its entire thickness and at least one part of the first phase change material of each second layer are fused together to form, from the first phase change material and the titanium-based material, a second phase change material comprising titanium.

11. A method for initialising a resistive memory according to claim 1, the method comprising circulating an electric current, forming an initialisation current, in each of the first and second layers, the initialisation current being adapted to generate a temperature gradient within said first and second layers involving melting of at least one part of the titanium-based material of each first layer over its entire thickness and at least part of the first phase change material of each second layer, said melting resulting in forming, from the first phase change material and the titanium-based material, a second phase change material comprising titanium.

12. The initialisation method according to claim 11, wherein the second phase change material has a concentration of titanium, from the molten titanium material, the initialisation current being selected to control said concentration.

13. The initialisation method according to claim 11, wherein the resistive memory has at least one intermediate active region, each intermediate active region being disposed between a first layer and a second layer, each intermediate active region comprising at least one third phase change material comprising titanium, the initialisation current also circulating in each intermediate active region, the initialisation current being adapted to generate a temperature gradient within each intermediate active region also involving melting of at least one part of the third phase change material of each intermediate active region, said melting resulting in forming, from the first phase change material and the titanium-based material and the third phase change material, a second phase change material comprising titanium.

14. A method for storing a message in a set of resistive memories, the set of resistive memories comprising a first sub-set of resistive memories and a second sub-set of resistive memories, distinct from the first sub-set of resistive memories, the storage method comprising a step of initialising each resistive memory of the first subset of resistive memories by implementing the initialisation method according to claim 11, the message stored being formed by the non-initialised resistive memories or of the resistive memories initialised.
